(19) United States
(12) Patent Application Publication
(10) Pub. No.: US 2019/0301022 A1
(43) Pub. Date: Oct. 3, 2019

(54) SYSTEMS AND METHODS FOR DEPOSITING A THIN FILM ONTO A FLEXIBLE SUBSTRATE

(71) Applicant: Global Solar Energy, Inc., Tucson, AZ (US)

(72) Inventor: Scott WIEDEMAN, Tucson, AZ (US)

(73) Assignee: Global Solar Energy, Inc., Tucson, AZ (US)

(21) Appl. No.: 15/944,189

(22) Filed: Apr. 3, 2018

(51) Int. Cl. C23C 18/12; H01L 21/02; H01L 21/285; C23C 18/08

(52) U.S. Cl. CPC C23C 18/1283; H01L 21/02628; H01L 21/02203; C23C 18/08; H01L 21/02425; C23C 18/1204; H01L 21/28556

(57) ABSTRACT

Systems and methods for depositing a thin film layer onto a flexible ferromagnetic substrate include a porous block in a deposition zone and a plurality of magnets embedded within the porous block. The magnets provide a downward force on a flexible ferromagnetic substrate being transported over the porous block, e.g., in a reel-to-reel system. Pressurized gas is forced upward through the porous block, providing an upward force that balances the downward force and supports the substrate at a desired height above the porous block. The substrate is thus held flat during transport through the deposition zone, enabling uniform deposition of a thin film layer.

### FIELD

This disclosure relates to systems and methods for depositing thin film layers onto flexible substrates. More specifically, the disclosed embodiments relate to magnetic air bearings for use in transporting flexible substrates through deposition zones.

### INTRODUCTION

Thin film coatings (e.g., semiconductor layers) may be applied to flexible substrates via chemical deposition. The deposition process may include transporting the substrate through a temperature-controlled chemical bath deposition zone. Chemical bath deposition is typically very sensitive to variation in the substrate flatness. Variations in the height of the substrate relative to heat sources below and the bath solution level above may affect factors such as depth, mixing, and heat transfer in the solution, leading to non-uniformity in the deposited layer. It is therefore desirable to hold the substrate flat during deposition; however, known solutions for flat transport of the substrate through the deposition zone suffer from drawbacks. For example, mechanically holding the substrate across an underlying platen at high tension is difficult and does not fully remove the substrate height variations. Magnets or a vacuum may be employed to pull the substrate flat against the platen, but friction in such a configuration often causes the substrate to tear, especially if bath solution seeps underneath. Accordingly, there is a need for systems and methods for flat transport of a flexible substrate through a deposition zone.

### SUMMARY

The present disclosure provides systems and methods relating to flat transport of a flexible substrate for thin film deposition. In some embodiments, a system for depositing a thin film semiconductor layer onto a flexible substrate may include a pay-out roll and a take-up roll, collectively configured to transport a flexible substrate through a deposition zone; a porous block having a substantially flat proximal surface disposed within the deposition zone and configured to support the substrate with air pressure, and a distal side opposite the substantially flat upper surface; a plurality of magnets embedded within the porous block; a pump configured to force pressurized gas through the porous block and thereby to maintain a gap between the substrate and the proximal surface of the porous block; a supply of a first solution containing cadmium; a first solution dispenser configured to dispense the first solution onto the substrate at a first longitudinal position within the deposition zone; a supply of a second solution containing sulfur; a second solution dispenser configured to dispense the second solution onto the substrate at a second longitudinal position within the deposition zone; and a heater configured to heat the substrate to a temperature sufficient to nucleate cadmium sulfide when the first and second solutions combine.

In some embodiments, a method of depositing a thin film n-type semiconductor layer onto a flexible substrate may include transporting the substrate through a deposition zone; within the deposition zone, pulling the substrate toward a porous underlying surface with a downward magnetic force; within the deposition zone, balancing the downward magnetic force with an upward force provided by pressurized gas flowing upward through the porous underlying surface; dispensing onto the substrate, at a first longitudinal position within the deposition zone, a first solution containing a metal selected from the group consisting of copper, silver, gold, zinc, cadmium, mercury, lead, boron, aluminum, gallium, indium, and thallium; and dispensing onto the substrate, at a second longitudinal position within the deposition zone, a second solution containing a chalcogen selected from the group consisting of oxygen, sulfur, selenium, and tellurium.

In some embodiments, a method of depositing a thin film n-type semiconductor layer onto a flexible substrate may include transporting the substrate through a deposition zone; within the deposition zone, pulling the substrate toward an underlying surface with a downward magnetic force; within the deposition zone, pushing the substrate away from the underlying surface with an upward force provided by pressurized gas flowing upward through pores of the underlying surface; dispensing onto the substrate, at a first longitudinal position within the deposition zone, a first solution containing a metal selected from the group consisting of copper, zinc, and cadmium; and dispensing onto the substrate, at a second longitudinal position within the deposition zone, a second solution containing sulfur.

Features, functions, and advantages may be achieved independently in various embodiments of the present disclosure, or may be combined in yet other embodiments, further details of which can be seen with reference to the following description and drawings.

### BRIEF DESCRIPTION OF THE DRAWINGS

FIG. 1 is a schematic diagram of an illustrative system for depositing a thin film layer onto a flexible substrate, according to aspects of the present teachings.

FIG. 2 is an isometric view of an illustrative porous block with embedded magnets to be used in conjunction with the system of FIG. 1.

FIG. 3 is an isometric view of an illustrative magnet assembly to be used in conjunction with the porous block of FIG. 2.

FIG. 4 is an isometric view depicting a bottom surface of an illustrative heater block to be used in conjunction with the system of FIG. 1.

FIG. 5 is an isometric view depicting a top surface of the heater block of FIG. 4.

FIG. 6 is an isometric view of an illustrative flexible substrate being transported through the system of FIG. 1.

FIG. 7 is a flow diagram of an illustrative method of depositing a thin-film n-type semiconductor layer onto a flexible substrate, according to aspects of the present teachings.

FIG. 8 is a flow diagram of another illustrative method of depositing a thin-film n-type semiconductor layer onto a flexible substrate.

### DESCRIPTION

Various aspects and examples of a system for depositing a thin film semiconductor layer onto a flexible substrate, as well as related methods, are described below and illustrated in the associated drawings. Unless otherwise specified, a system for thin-film deposition and/or its various components may, but are not required to, contain at least one of the structures, components, functionality, and/or variations described, illustrated, and/or incorporated herein. Furthermore, unless specifically excluded, the process steps, structures, components, functionalities, and/or variations described, illustrated, and/or incorporated herein in connection with the present teachings may be included in other similar devices and methods, including being interchangeable between disclosed embodiments. The following description of various examples is merely illustrative in nature and is in no way intended to limit the disclosure, its application, or uses. Additionally, the advantages provided by the examples and embodiments described below are illustrative in nature and not all examples and embodiments provide the same advantages or the same degree of advantages.

### Overview

The present disclosure is directed to systems and methods for depositing a thin film layer onto a flexible substrate. According to aspects of the present teachings, a system for depositing a thin film layer onto a flexible substrate includes a deposition zone such as a chemical bath, chemical vapor deposition chamber, or sputtering chamber. The flexible substrate is transported through the deposition zone so that a thin film can be deposited on it. The uniformity of the deposited film is at least partly determined by the flatness of the substrate during transport. Accordingly, the thin-film deposition systems disclosed herein include a magnetic air bearing system configured to hold the substrate flat during transport through the deposition zone. A magnetic air bearing system may include a porous surface disposed within the deposition zone such that transporting the flexible substrate through the deposition zone includes passing the flexible substrate over the porous surface. The porous surface contains a plurality of magnets configured to exert a downward force tending to pull the substrate down toward the porous surface. An opposing upward force is provided by pressurized gas flowing through the porous surface. The opposing upward and downward forces are configured to result in a net force that maintains the flexible substrate at a selected height above the porous surface; i.e., a gap is maintained between the substrate and the porous surface. The balanced upward and downward forces hold the flexible substrate in a substantially flat state, allowing for substantially uniform deposition of a thin film layer.

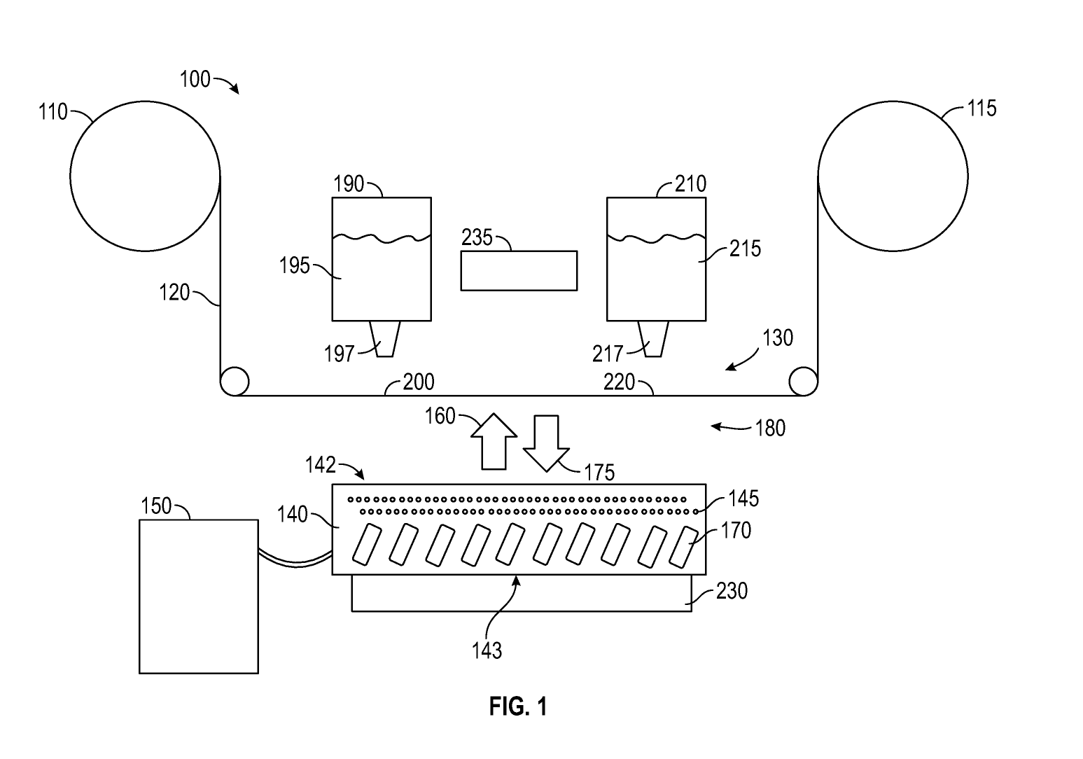

FIG. 1 is a schematic block diagram depicting an illustrative deposition system, generally indicated at 100, for depositing a thin film onto a flexible substrate, according to aspects of the present disclosure. Deposition system 100 includes a pay-out roll 110 and a take-up roll 115 configured to transport flexible ferromagnetic substrate 120 through a deposition zone 130. Substrate 120, which may also be referred to as a web, is fed out from pay-out roll 110 and wound onto take-up roll 115. For example, take-up roll 115 may be configured to rotate such that substrate 120 is unwound from pay-out roll 110, pulled through deposition zone 130, and wound onto take-up roll 115. Pay-out roll 110 and take-up roll 115 may be part of a reel-to-reel process (also known as a roll-to-roll or web process). Substrate 120 may include thin film layers and/or semiconductor layers; i.e., deposition system 100 may be used to deposit new thin film layers on top of existing thin film layers.

A porous block 140, which may also be referred to as a porous platen, is disposed within deposition zone 130. Porous block 140 includes a substantially flat top porous block surface 142 proximal substrate 120 and a bottom porous block surface 143 distal substrate 120, opposite the top porous block surface. Porous block 140 includes a plurality of holes, channels, and/or pores 145. The size of pores 145 and the distribution of the pores throughout porous block 140 is sufficient to enable air or another gas to flow through a surface of the porous block approximately uniformly. Porous block 140 may be formed by porous graphite, foam, or another suitable porous material. In other examples, porous block 140 is formed by metal or another otherwise non-porous surface into which orifices have been cut or drilled.

A gas source 150 forces a pressurized gas (not pictured) through porous block 140 (i.e., through pores 145). Gas source 150 may be a pump, compressor, or any other source of pressurized gas. The gas may be air, an inert gas, or any other suitable gas. Gas pushes upward on objects above top porous block surface 142 with an upward force 160. Porous block 140 is thus configured to support substrate 120 with gas pressure, including air pressure if the gas is air. Upward force 160 is sufficient to prevent direct physical contact between substrate 120 and top porous block surface 142. In some embodiments, the flow of gas through porous block 140 is approximately uniform across top porous block surface 142, such that upward force 160 is approximately equal at all points at a given height above the top porous block surface. Accordingly, an expanse of substrate 120 being transported through deposition zone 130 above and substantially parallel to top porous block surface 142 is pushed uniformly upwards by upward force 160 (i.e., each portion of the expanse experiences the same upward force). In other embodiments, upward force 160 is not uniform across top porous block surface 142.

A plurality of magnets 170 is embedded in porous block 140. Magnets 170 are configured to provide a downward force 175 on a ferromagnetic object, such as substrate 120, disposed above porous block 140. Upward force 160 and downward force 175 are configured to maintain substrate 120 at a desired height above top porous block surface 142 in deposition zone 130; in other words, the upward force and downward force maintain a gap 180 between the substrate and the top porous block surface. The size of gap 180 may be at least partially determined by the strengths and positions of magnets 170, the size and distribution of pores 145, the pressure of the gas, and the weight and magnetic properties of substrate 120. These factors, among others, may be adjusted to balance upward force 160 and downward force 175 to attain a desired gap 180.

In some embodiments, the size of gap 180 is between 0.5 and 500 microns. In some embodiments, the size of gap 180 is between 5 and 50 microns. In some embodiments, the size of gap 180 is between 10 and 20 microns. In some embodiments, the size of gap 180 is larger near the edges of substrate 120 than at the center, such that the substrate forms a channel with upturned edges, which may help to contain fluid deposited on the substrate. The layer of air (or other gas) in gap 180 may be considered an air bearing. Substrate 120 is transported on the air bearing substantially without friction, or with minimal friction.

Within deposition zone 130, a thin film is deposited onto substrate 120. The thin film may be a semiconductor layer. Deposition zone 130 may be a chemical bath, a vapor deposition chamber, or any other location suitable for deposition of a thin film. A first supply 190 of a first solution 195 is coupled to a first solution dispenser 197 configured to dispense the first solution onto substrate 120 at a first longitudinal position 200 within the deposition zone. First solution dispenser 197 may be a fluid outlet, spray nozzle, pipette, or any other dispenser configured to dispense first solution 195 onto substrate 120. A second supply 210 of a second solution 215 is coupled to a second solution dispenser 217 configured to dispense the second solution onto substrate 120 at a second longitudinal position 220 within the deposition zone.

First longitudinal position 200 and second longitudinal position 220 may be substantially overlapping, substantially non-overlapping, or partially overlapping. Second solution dispenser 217 may be the same type of dispenser as dispenser 197, or a different type. In some embodiments, first solution 195 contains cadmium and second solution 215 contains sulfur, and the thin film deposited on substrate 120 is a cadmium sulfide thin film. A cadmium sulfide thin film deposited in accordance with aspects of the present teachings may form part of a photovoltaic cell, such as an n-type semiconductor layer suitable for forming a p-n junction with a p-type layer.

System 100 includes a heater 230 configured to heat substrate 120. Heater 230 may be used to maintain substrate 120 and/or first solution 195 and/or second solution 215 at temperatures suitable to facilitate a desired chemical or physical process. For example, first solution 195 may contain cadmium and second solution 215 may contain sulfur, and heater 230 may be configured to heat substrate 120 to a temperature sufficient to nucleate cadmium sulfide when the first and second solutions combine. In some embodiments, heater 230 heats first solution 195 and second solution 215 to a temperature in the range of 55-75° C.

Heater 230 may be configured to provide heat via combustion, resistive heating, chemical reactions, or any other suitable process. Heater 230 may be disposed adjacent bottom porous block surface 143, as depicted in FIG. 1. In some embodiments, heater 230 is disposed within porous block 140. Air flow through porous block 140 may facilitate heat transfer to substrate 120. Heat transfer to substrate 120 may occur via evaporation, convection, conduction, and/or radiation. Porous block 140 may absorb heat from heater 230 and transfer heat to substrate 120.

Optionally, system 100 may further include a second heater 235, which may be disposed above substrate 120. Second heater 235 may help to maintain substrate 120 at a desired temperature gradient, or at a uniform temperature. Additionally, second heater 235 may reduce or prevent increases in heat transfer from the top side of substrate 120 that result from small variations in the height of the substrate above porous block 140.

A stirrer, mixer, spinner, or other mechanism for combining the first and second solutions may be included in deposition zone 130. In some embodiments, a layer, barrier, or flexible membrane floats on top of the solution on substrate 120 to prevent or reduce heat loss by evaporation and other mechanisms, which may lead to greater uniformity of solution temperature and/or substrate temperature.

### Examples, Components, and Alternatives

The following sections describe selected aspects of illustrative systems and methods for depositing a thin film layer onto a flexible substrate. The examples in these sections are intended for illustration and should not be interpreted as limiting the entire scope of the present disclosure. Each section may include one or more distinct embodiments or examples, and/or contextual or related information, function, and/or structure.

### A. Illustrative Porous Block with Magnets

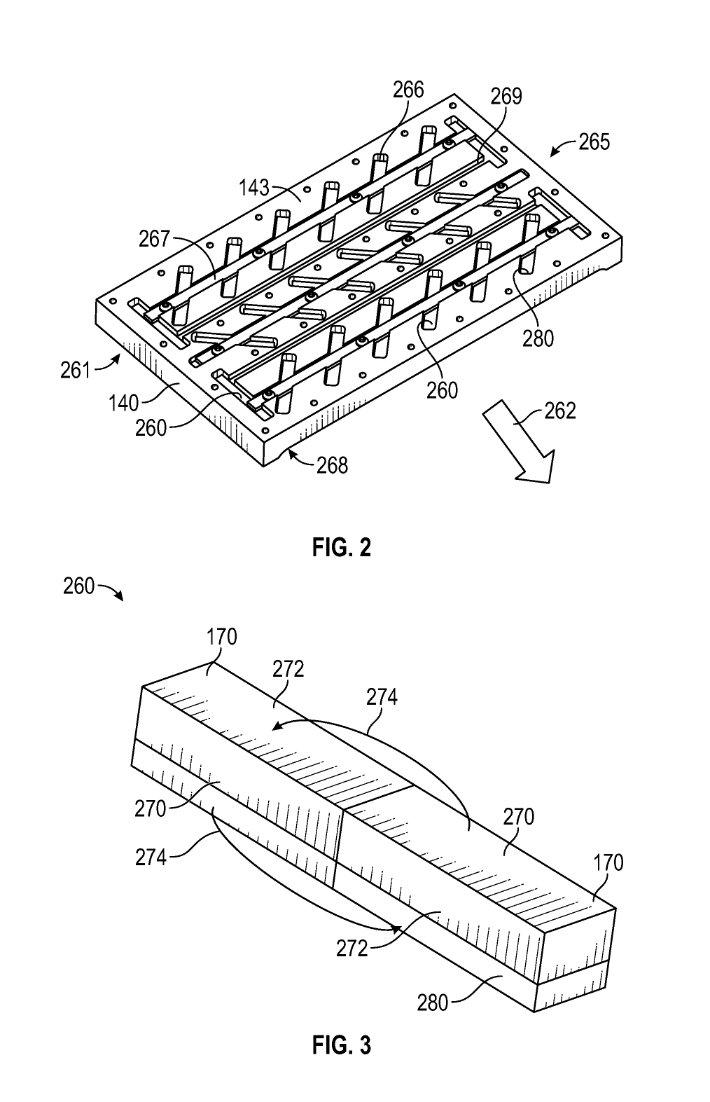

FIGS. 2-3 depict an illustrative porous block 140 including embedded magnets 170 for use in conjunction with deposition system 100, described above.

Illustrative porous block 140 includes embedded magnets 170. Magnets 170 are disposed in magnet assemblies 260 (see FIG. 3 and associated description below). Magnet assemblies 260 are disposed in porous block 140 adjacent bottom porous block surface 143 in a plurality of rows 261. Magnet assemblies 260 are oriented diagonally relative to a direction 262, which is the direction of transport of substrate 120. Rows 261 may form a zig-zag or chevron pattern 265. Porous block 140 may include additional magnet assemblies 260 outside of chevron pattern 265 disposed, for example, at edges of the porous block.

Porous block 140 includes openings or slots 266 shaped to contain magnet assemblies 260 within the porous block and/or against bottom porous block surface 143. One or more retention bars 267 is configured to retain magnet assemblies 260 within slots 266. Porous block 140 includes additional openings shaped to hold retention bars 267, which may be retained within the additional openings by screws, braces, adhesives, or any other suitable mechanism. In other embodiments, porous block 140 does not include additional openings to hold retention bars 267, and the retention bars are held against bottom porous block surface 143.

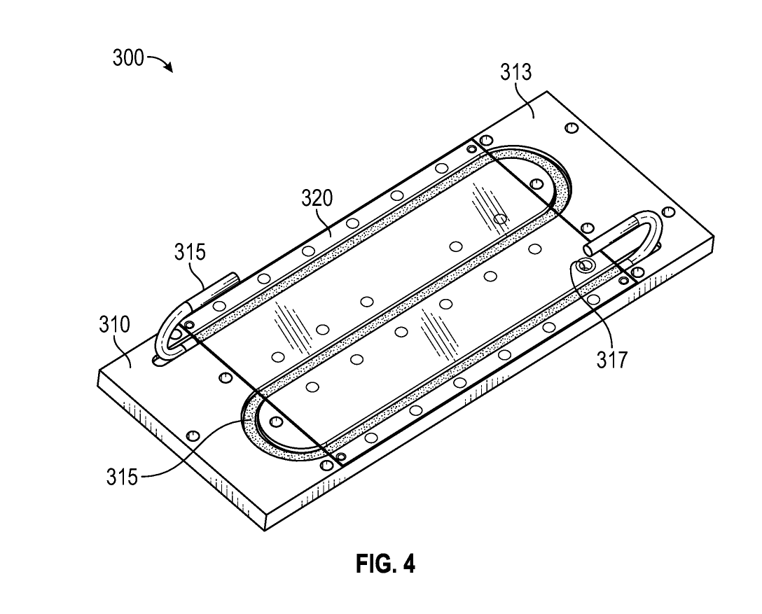

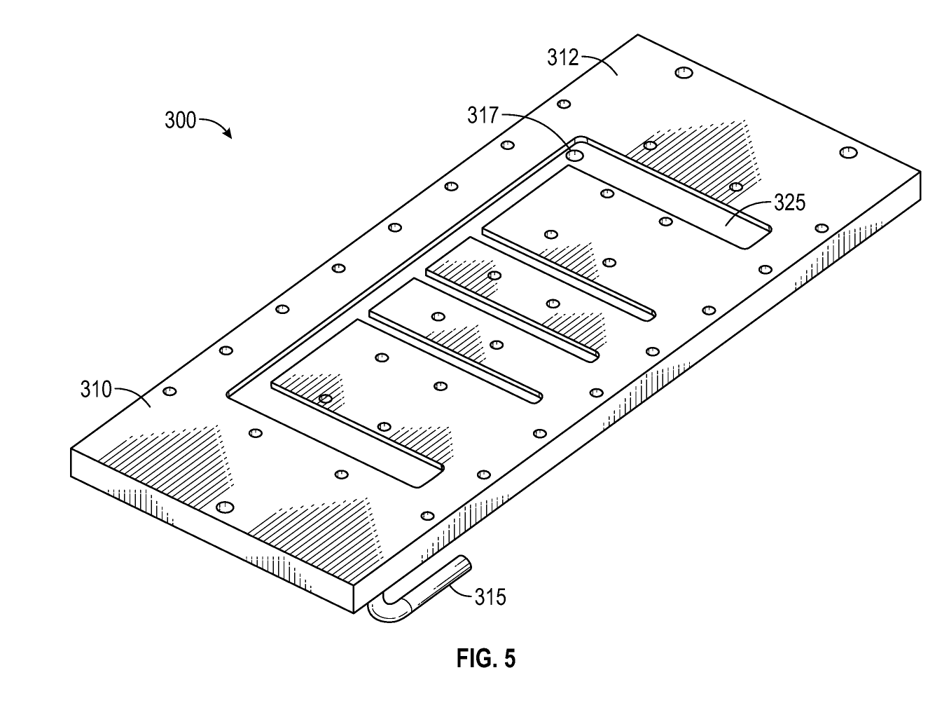

Top porous block surface 142 includes a depression 268 extending between opposing edges of the surface. Depression 268 is configured to contain substrate 120 and/or to confine liquid solutions to the top of the substrate as the substrate passes through deposition zone 130; for example, the depression may have a width slightly larger than the width of the substrate. Depression 268 may have a concave profile near its lateral edges (therefore also near the lateral edges of the substrate) to confine liquids within the deposition zone. Depression 268 also tends to confine pressurized gas 155 emerging from top porous block surface 142, such that the pressurized gas remains between the top surface of the porous block and substrate 120. Porous block 140 includes bolt holes extending between top porous block surface 142 and bottom porous block surface 143. The bolt holes are aligned with corresponding bolt holes in heater 230 (see FIGS. 4-5) and are configured to receive bolts or screws fastening porous block 140 and the heater together.

Porous block 140 includes one or more air flow channels 269. Air flow channels 269 are formed in bottom porous block surface 143. Air flow channels 269 are configured to allow pressurized gas 155 (which may or may not be air) to flow between porous block 140 and heater 230 (see FIGS. 4-5 and associated description of an example of heater 230). Air flow channels 269 may be formed between each pair of adjacent rows 261 of magnet assemblies 260.

FIG. 3 depicts an illustrative magnet assembly 260. Each magnet assembly 260 includes a pair of magnets 170 oriented such that north pole 270 of a first magnet is adjacent south pole 272 of a second magnet, and the south pole of the first magnet is adjacent the north pole of the second magnet. The two magnets 170 of the magnet assembly 260 may be in contact with each other. Magnetic field lines 274 corresponding to a magnetic field 275 produced by magnet assembly 260 are illustrated by arrows in FIG. 3. Magnetic field 275 attracts a ferromagnetic substrate 120, pulling the substrate toward magnet assembly 260. Magnet assemblies 260 may be disposed in slots 266 of chevron pattern 265 such that the magnetic field 275 of each magnet assembly is typically oriented opposite the magnetic field of adjacent magnet assemblies (i.e., magnetic field lines 274 of adjacent magnet assemblies do not point in the same direction).

Magnet assembly 260 includes a shunt 280 to which the pair of magnets 170 is attached. Shunt 280 fixes the positions and orientations of the pair of magnets 170 relative to each other. Shunt 280 may be steel, iron, aluminum, or another material. Magnets 170 may be affixed to shunt 280 by adhesive, screws, magnetic attraction, or may be retained against the shunt by retention bar 267.

### B. Illustrative Heater Assembly

FIGS. 4-5 depict an illustrative heater assembly 300, which is an example of a heater 230 described above for use in conjunction with deposition system 100.

Heater assembly 300 includes heater block 310 with top heater block surface 312 and bottom heater block surface 313, as well as heating element 315. Heater block 310 is a block of material with high heat conductivity, such as aluminum, which conducts heat transferred from heating element 315. Heater block 310 includes an inlet 317 configured to transport pressurized gas 155 from gas source 150 to top heater block surface 312 and through porous block 140. Inlet 317 may include pipe fittings or hose fittings configured to connect to a pipe or hose.

Heating element 315, which may also be referred to as a heater, is embedded in heater block 310. As shown in FIG. 4, bottom heater block surface 313 includes an opening shaped to contain at least a portion of heating element 315. Heating element 315 may be a resistive heating element. Heater assembly 300 may include a temperature-stabilizing mechanism, such as one or more temperature sensors (e.g., thermocouples) coupled in a feedback loop to circuitry controlling the electrical power provided to heating element 315. The temperature-stabilizing mechanism may be configured to maintain substrate 120, or deposited solutions 195 and 215, at a desired temperature or temperature gradient. Heater block 310 may include wells or other openings in which thermocouples or other temperature sensors may be disposed.

Bottom heater block surface 313 is at least partially covered with a barrier or sheet 320 configured to retain heating element 315 within the opening and/or against the bottom heater block surface. Sheet 320 may also retain thermocouples or other temperature sensors against bottom heater block surface 313 or within wells in heater block 310. Sheet 320 may be plastic, glass, or any other material suitable to retain heating element 315 without sustaining damage from the heat of the heating element.

FIG. 5 depicts top heater block surface 312 of heater block 310. Top heater block surface 312 includes a vent 325 formed by one or more indentations in the top heater block surface. Inlet 317 conveys pressurized gas 155 into vent 325. Pressurized gas 155 exiting inlet 317 flows into vent 325, and pressurized gas in the vent flows into porous block 140. That is, vent 325 is configured to allow gas to flow between heater block 310 and porous block 140. The size and shape of vent 325 are configured such that pressurized gas 155 enters porous block 140 through an expanse of bottom porous block surface 143 and provides a substantially spatially symmetric or spatially uniform upward force when exiting top porous block surface 142. Vent 325 may be configured to be in fluid communication with one or more air flow channels 269 of porous block 140.

Heater block 310 includes bolt holes aligned with corresponding bolt holes in porous block 140 and configured to receive screws or bolts fastening the heater block to the porous block, with top heater block surface 312 contacting bottom porous block surface 143. The positions of bolt holes in porous block 140 and heater block 310 may be designed to reduce or prevent deformation of the porous block under pressure from pressurized gas 155. For example, the bolt holes may be distributed substantially uniformly or substantially symmetrically in porous block 140 and heater block 310.

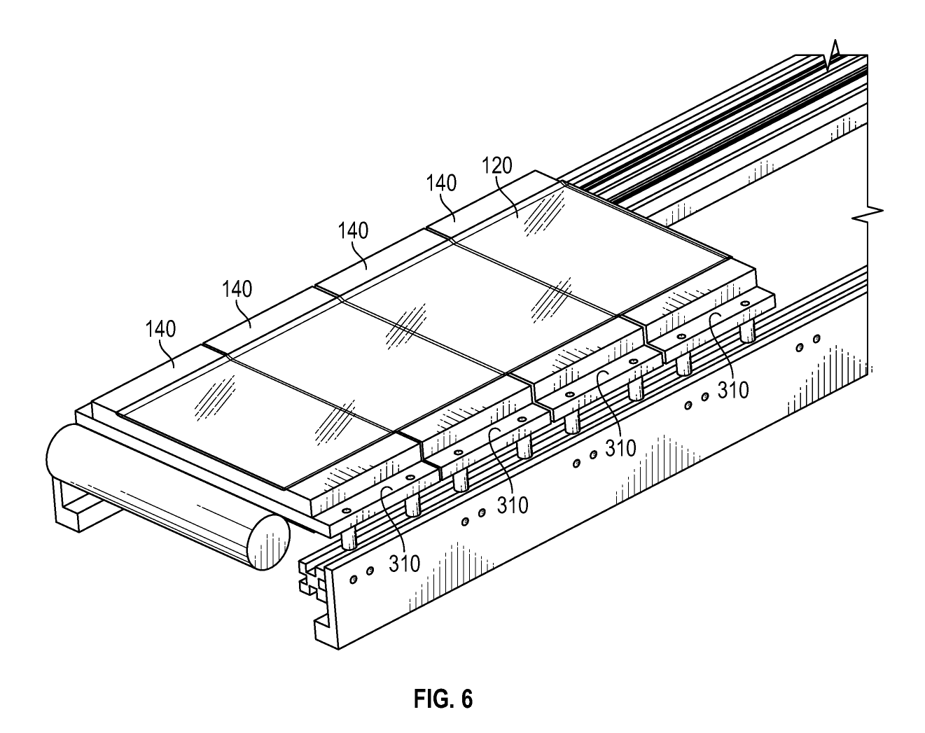

Deposition system 100 may include one or more pairs of connected heater blocks 310 and porous blocks 140. FIG. 6 depicts exemplary pairs of connected heater blocks 310 and porous blocks 140 disposed edge-to-edge such that depressions 268 of adjacent porous blocks form a substantially continuous channel containing substrate 120 as it passes through deposition zone 130.

### C. First Illustrative Method

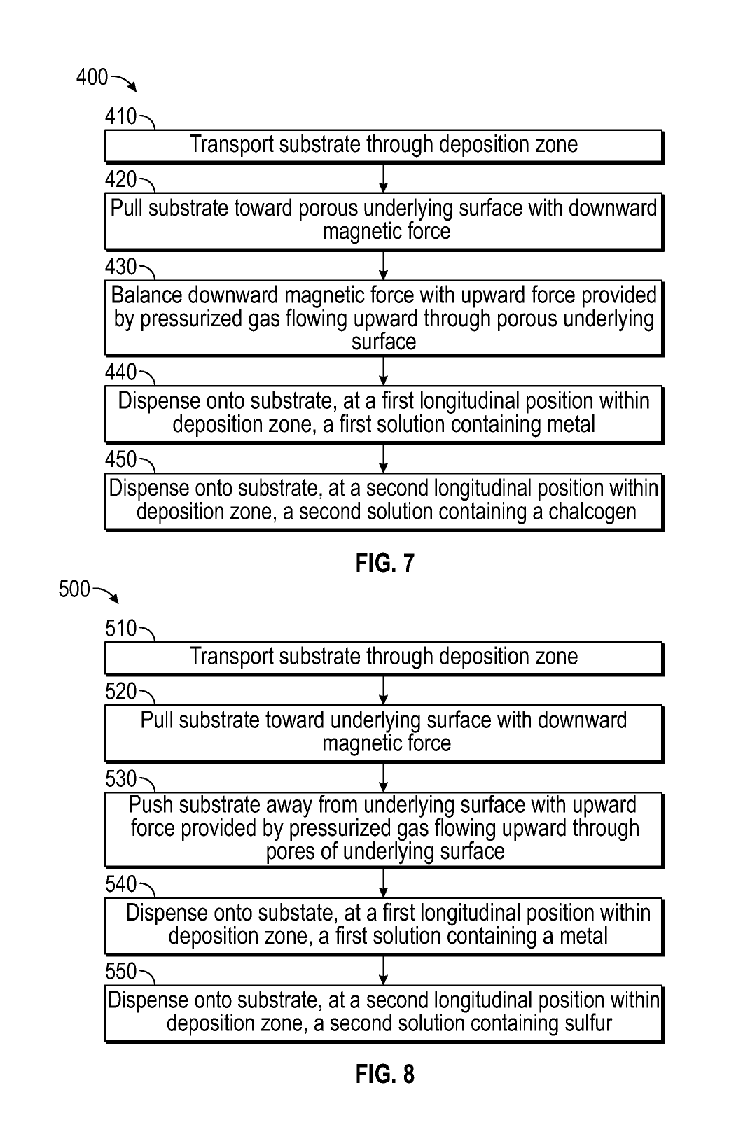

This section describes steps of an illustrative method 400 for depositing a thin film n-type semiconductor layer onto a flexible substrate; see FIG. 7. Aspects of deposition system 100 may be utilized in the method steps described below. Where appropriate, reference may be made to components and systems that may be used in carrying out each step. These references are for illustration, and are not intended to limit the possible ways of carrying out any particular step of the method.

FIG. 7 is a flowchart illustrating steps performed in an illustrative method, and may not recite the complete process or all steps of the method. Although various steps of method 400 are described below and depicted in FIG. 7, the steps need not necessarily all be performed, and in some cases may be performed simultaneously or in a different order than the order shown.

At step 410, method 400 includes transporting a flexible substrate through a deposition zone. The flexible substrate is configured to be attracted to a magnet; for example, the flexible substrate may be made of a ferromagnetic material, or may include ferromagnetic components. The substrate may be a metal foil. The deposition zone may be a chemical bath, chemical vapor deposition chamber, sputtering chamber, or any other chamber suitable for depositing a thin film n-type semiconductor layer onto a substrate.

At step 420, method 400 includes pulling the substrate toward a porous underlying surface with a downward magnetic force. The substrate is pulled by the magnetic force within the deposition zone; the porous underlying surface and/or the source of the magnetic force may also be disposed within the deposition zone. The porous underlying surface may be a surface of a block of porous graphite. The magnetic force may be provided by one or more magnets disposed beneath the porous surface, adjacent the porous surface, and/or within the porous surface. The magnets may be embedded in the porous surface or another part of a porous block in a chevron pattern.

At step 430, method 400 includes balancing the downward magnetic force within the deposition zone with an upward force provided by pressurized gas flowing upward through the porous underlying surface. The pressurized gas may be air, nitrogen, argon, or any other gas suitable for the conditions of the deposition zone. The upward force may be sufficient to prevent direct physical contact between the substrate and the underlying surface. The upward force may be sufficient to maintain the substrate at a distance in the range of 10-20 micrometers from the underlying surface (i.e., the upward and downward forces are balanced at a distance in the range of 10-20 micrometers from the surface).

At step 440, method 400 includes dispensing onto the substrate, at a first longitudinal position within the deposition zone, a first solution containing a metal such as copper, silver, gold, zinc, cadmium, mercury, lead, boron, aluminum, gallium, indium, or thallium.

At step 450, method 400 includes dispensing onto the substrate, at a second longitudinal position within the deposition zone, a second solution containing a chalcogen such as oxygen, sulfur, selenium, or tellurium.

Method 400 may further include heating the first solution and/or the second solution to a temperature in the range of 55-75 degrees Celsius. The first and/or second solutions may be heated to a temperature sufficient to facilitate a desired chemical reaction between components of the solutions.

### D. Second Illustrative Method

This section describes steps of another illustrative method 500 for depositing a thin film n-type semiconductor layer onto a flexible substrate; see FIG. 8. Aspects of deposition system 100 may be utilized in the method steps described below. Where appropriate, reference may be made to components and systems that may be used in carrying out each step. These references are for illustration, and are not intended to limit the possible ways of carrying out any particular step of the method.

FIG. 8 is a flowchart illustrating steps performed in an illustrative method, and may not recite the complete process or all steps of the method. Although various steps of method 500 are described below and depicted in FIG. 8, the steps need not necessarily all be performed, and in some cases may be performed simultaneously or in a different order than the order shown.

At step 510, method 500 includes transporting a flexible substrate through a deposition zone. The flexible substrate is configured to be attracted to a magnet; for example, the flexible substrate may be made of a ferromagnetic material, or include ferromagnetic components. The substrate may be a metal foil. The deposition zone may be a chemical bath, chemical vapor deposition chamber, sputtering chamber, or any other chamber suitable for depositing a thin film n-type semiconductor layer onto a substrate.

At step 520, method 500 includes pulling the substrate toward an underlying surface with a downward magnetic force. The substrate is pulled downward within the deposition zone.

At step 530, method 500 includes pushing the substrate away from the underlying surface with an upward force provided by pressurized gas flowing upward through pores of the underlying surface. The substrate is pushed upward within the deposition zone. The upward force may be sufficient to maintain the substrate at a distance in the range of 10-20 micrometers from the underlying surface in the presence of the downward magnetic force. The underlying surface may be a surface of a porous graphite block. The downward magnetic force may be provided by a plurality of magnets embedded in the porous graphite block.

At step 540, method 500 includes dispensing onto the substrate, at a first longitudinal position within the deposition zone, a first solution containing a metal such as copper, zinc, or cadmium.

At step 550, method 500 includes dispensing onto the substrate, at a second longitudinal position within the deposition zone, a second solution containing sulfur.

Method 500 may further include heating the underlying surface with a heater block. The heater block may be attached to the surface; for example, the surface may be a surface of a porous graphite block, and the heater block may be attached to a side of the porous graphite block distal the substrate. Heat from the heater block may heat the first and/or second solutions. The heater block may be configured to maintain the first and/or second solutions at a desired temperature.

### E. Additional Examples and Illustrative Combinations

This section describes additional aspects and features of deposition system 100, presented without limitation as a series of paragraphs, some or all of which may be alphanumerically designated for clarity and efficiency. Each of these paragraphs can be combined with one or more other paragraphs, and/or with disclosure from elsewhere in this application, in any suitable manner. Some of the paragraphs below expressly refer to and further limit other paragraphs, providing without limitation examples of some of the suitable combinations.

A0. A system for depositing a thin film semiconductor layer onto a flexible substrate, comprising a pay-out roll and a take-up roll, collectively configured to transport a flexible substrate through a deposition zone; a porous block having a substantially flat proximal surface disposed within the deposition zone and configured to support the substrate with air pressure, and a distal side opposite the substantially flat upper surface; a plurality of magnets embedded within the porous block; a pump configured to force pressurized gas through the porous block and thereby to maintain a gap between the substrate and the proximal surface of the porous block; a supply of a first solution containing cadmium; a first solution dispenser configured to dispense the first solution onto the substrate at a first longitudinal position within the deposition zone; a supply of a second solution containing sulfur; a second solution dispenser configured to dispense the second solution onto the substrate at a second longitudinal position within the deposition zone; and a heater configured to heat the substrate to a temperature sufficient to nucleate cadmium sulfide when the first and second solutions combine.

A1. The system of paragraph A0, wherein the porous block is formed of porous graphite.

A2. The system of any one of paragraphs A0 through A1, wherein the heater is a first heater disposed adjacent to the distal side of the porous block.

A3. The system of any one of paragraphs A0 through A2, further comprising a second heater disposed above the proximal surface of the porous block.

A4. The system of any one of paragraphs A2 through A3, wherein the first heater is embedded in a heater block which is attached to the porous block.

A5. The system of paragraph A4, wherein at least one air flow channel is formed in the porous block and configured to allow air flow between the heater block and the porous block.

A6. The system of any one of paragraphs A0 through A5, wherein the magnets are embedded in slots formed in the distal side of the porous block.

A7. The system of paragraph A6, further comprising a retention bar attached to the distal side of the porous block and configured to retain the magnets within the slots.

A8. The system of any one of paragraphs A0 through A7, wherein the magnets are oriented diagonally relative to a direction of transport of the substrate, and are arranged in a plurality of rows with an air flow channel formed between each pair of adjacent rows.

B0. A method of depositing a thin film n-type semiconductor layer onto a flexible substrate, comprising transporting the substrate through a deposition zone; within the deposition zone, pulling the substrate toward a porous underlying surface with a downward magnetic force; within the deposition zone, balancing the downward magnetic force with an upward force provided by pressurized gas flowing upward through the porous underlying surface; dispensing onto the substrate, at a first longitudinal position within the deposition zone, a first solution containing a metal selected from the group consisting of copper, silver, gold, zinc, cadmium, mercury, lead, boron, aluminum, gallium, indium, and thallium; and dispensing onto the substrate, at a second longitudinal position within the deposition zone, a second solution containing a chalcogen selected from the group consisting of oxygen, sulfur, selenium, and tellurium.

B1. The method of paragraph B0, wherein the upward force is sufficient to prevent direct physical contact between the substrate and the underlying surface.

B2. The method of any one of paragraphs B0 through B1, wherein the upward force is sufficient to maintain the substrate at a distance in the range of 10-20 micrometers (μm) from the underlying surface.

B3. The method of any one of paragraphs B0 through B2, wherein the underlying surface is a proximal surface of a porous block, and the downward magnetic force is provided by a plurality of magnets embedded in the porous block.

B4. The method of paragraph B3, wherein the magnets are embedded in the porous block in a chevron pattern.

B5. The method of any one of paragraphs B3 through B4, wherein the porous block is constructed from porous graphite.

B6. The method of any one of paragraph B0 through B5, further comprising heating the first and second solutions to a temperature in the range of 55-75 degrees Celsius.

C0. A method of depositing a thin film n-type semiconductor layer onto a flexible substrate, comprising: transporting the substrate through a deposition zone; within the deposition zone, pulling the substrate toward an underlying surface with a downward magnetic force; within the deposition zone, pushing the substrate away from the underlying surface with an upward force provided by pressurized gas flowing upward through pores of the underlying surface; dispensing onto the substrate, at a first longitudinal position within the deposition zone, a first solution containing a metal selected from the group consisting of copper, zinc, and cadmium; and dispensing onto the substrate, at a second longitudinal position within the deposition zone, a second solution containing sulfur.

C1. The method of paragraph C0, wherein the upward force is sufficient to maintain the substrate at a distance in the range of 10-20 micrometers (μm) from the underlying surface.

C2. The method of any one of paragraphs C0 through C1, wherein the underlying surface is a proximal surface of a porous graphite block, and wherein the downward magnetic force is provided by a plurality of magnets embedded in the porous graphite block.

C3. The method of paragraph C2, further comprising heating the porous graphite block with a heater block attached to a distal side of the porous graphite block.

### Advantages, Features, Benefits

The different embodiments and examples of the deposition system described herein provide several advantages over known solutions for conveying a flexible substrate through a deposition zone. For example, illustrative embodiments and examples described herein allow a flexible ferromagnetic substrate to be transported through a deposition zone while remaining substantially flat.

Additionally, and among other benefits, illustrative embodiments and examples described herein allow a flexible ferromagnetic substrate to be transported through a deposition zone substantially without friction, with good heat transfer and substantially constant temperature across the substrate (i.e., in a direction orthogonal to the direction of substrate transport), in a system that accommodates relatively high process temperatures and is robust to liquid spills and corrosive vapors.

No known system or device can perform these functions. However, not all embodiments and examples described herein provide the same advantages or the same degree of advantage.

### CONCLUSION

The disclosure set forth above may encompass multiple distinct examples with independent utility. Although each of these has been disclosed in its preferred form(s), the specific embodiments thereof as disclosed and illustrated herein are not to be considered in a limiting sense, because numerous variations are possible. To the extent that section headings are used within this disclosure, such headings are for organizational purposes only. The subject matter of the disclosure includes all novel and nonobvious combinations and subcombinations of the various elements, features, functions, and/or properties disclosed herein. The following claims particularly point out certain combinations and subcombinations regarded as novel and nonobvious. Other combinations and subcombinations of features, functions, elements, and/or properties may be claimed in applications claiming priority from this or a related application. Such claims, whether broader, narrower, equal, or different in scope to the original claims, also are regarded as included within the subject matter of the present disclosure.

1. A system for depositing a thin film semiconductor layer onto a flexible substrate, comprising:
a pay-out roll and a take-up roll, collectively configured to transport a flexible substrate through a deposition zone;
a porous block having a substantially flat proximal surface disposed within the deposition zone and configured to support the substrate with air pressure, and a distal side opposite the substantially flat upper surface;
a plurality of magnets embedded within the porous block;
a pump configured to force pressurized gas through the porous block and thereby to maintain a gap between the substrate and the proximal surface of the porous block,
wherein the pressurized gas is dispensed uniformly across the deposition zone, such that the gap is equal at all points across the deposition zone;
a supply of a first solution containing cadmium;
a first solution dispenser configured to dispense the first solution onto the substrate at a first longitudinal position within the deposition zone;
a supply of a second solution containing sulfur;
a second solution dispenser configured to dispense the second solution onto the substrate at a second longitudinal position within the deposition zone; and
a heater configured to heat the substrate to a temperature sufficient to nucleate cadmium sulfide when the first and second solutions combine.

2. The system of claim 1, wherein the porous block is formed of porous graphite.

3. The system of claim 1, wherein the heater is a first heater disposed adjacent to the distal side of the porous block.

4. The system of claim 3, further comprising a second heater disposed above the proximal surface of the porous block.

5. The system of claim 3, wherein the first heater is embedded in a heater block which is attached to the porous block.

6. The system of claim 5, wherein at least one air flow channel is formed in the porous block and configured to allow air flow between the heater block and the porous block.

7. The system of claim 6, wherein the magnets are embedded in slots formed in the distal side of the porous block.

8. The system of claim 7, further comprising a retention bar attached to the distal side of the porous block and configured to retain the magnets within the slots.

9. The system of claim 8, wherein the magnets are oriented diagonally relative to a direction of transport of the substrate, and are arranged in a plurality of rows with an air flow channel formed between each pair of adjacent rows.

10. A method of depositing a thin film n-type semiconductor layer onto a flexible substrate, comprising:
transporting the substrate through a deposition zone;
while transporting the substrate through the deposition zone, pulling the substrate toward a porous underlying surface with a downward magnetic force;
while transporting the substrate through the deposition zone, balancing the downward magnetic force with an upward force provided by pressurized gas flowing upward through the porous underlying surface,
wherein the pressurized gas is dispensed uniformly across the deposition zone, such that the upward force is equal at all points across the deposition zone;
while transporting the substrate through the deposition zone, dispensing onto the substrate, at a first longitudinal position within the deposition zone, a first solution containing a metal selected from the group consisting of copper, silver, gold, zinc, cadmium, mercury, lead, boron, aluminum, gallium, indium, and thallium; and
while transporting the substrate through the deposition zone, dispensing onto the substrate, at a second longitudinal position within the deposition zone, a second solution containing a chalcogen selected from the group consisting of oxygen, sulfur, selenium, and tellurium.

11. The method of claim 10, wherein the upward force is sufficient to prevent direct physical contact between the substrate and the underlying surface.

12. The method of claim 11, wherein the upward force is sufficient to maintain the substrate at a distance in the range of 10-20 micrometers (μm) from the underlying surface.

13. The method of claim 10, wherein the underlying surface is a proximal surface of a porous block, and the downward magnetic force is provided by a plurality of magnets embedded in the porous block.

14. The method of claim 13, wherein the magnets are embedded in the porous block in a chevron pattern.

15. The method of claim 10, wherein the underlying surface is constructed from porous graphite.

16. The method of claim 10, further comprising heating the first and second solutions to a temperature in the range of 55-75 degrees Celsius.

17. A method of depositing a thin film n-type semiconductor layer onto a flexible substrate, comprising:
transporting the substrate through a deposition zone;
while transporting the substrate through the deposition zone, pulling the substrate toward an underlying surface with a downward magnetic force;
while transporting the substrate through the deposition zone, pushing the substrate away from the underlying surface with an upward force provided by pressurized gas flowing upward through pores of the underlying surface;
wherein the pressurized gas is dispensed uniformly across the deposition zone, such that the upward force is equal at all points across the deposition zone;
while transporting the substrate through the deposition zone, dispensing onto the substrate, at a first longitudinal position within the deposition zone, a first solution containing a metal selected from the group consisting of copper, zinc, and cadmium; and
while transporting the substrate through the deposition zone, dispensing onto the substrate, at a second longitudinal position within the deposition zone, a second solution containing sulfur.

18. The method of claim 17, wherein the upward force is sufficient to maintain the substrate at a distance in the range of 10-20 micrometers (μm) from the underlying surface.

19. The method of claim 17, wherein the underlying surface is a proximal surface of a porous graphite block, and wherein the downward magnetic force is provided by a plurality of magnets embedded in the porous graphite block.

20. The method of claim 19, further comprising heating the porous graphite block with a heater block attached to a distal side of the porous graphite block.
